(19) United States
(12) Patent Application Publication
(10) Pub. No.: US 2026/0162587 A1
(43) Pub. Date: Jun. 11, 2026

(54) DISPLAY PANEL AND DISPLAY DEVICE

(71) Applicant: BOE Technology Group Co., Ltd., Beijing (CN)

(72) Inventors: Pan XU, Beijing (CN); Ying HAN, Beijing (CN); Xing ZHANG, Beijing (CN); Donghui ZHAO, Beijing (CN); Chengyuan LUO, Beijing (CN); Guangshuang LV, Beijing (CN); Cheng XU, Beijing (CN)

(73) Assignee: BOE Technology Group Co., Ltd., Beijing (CN)

(21) Appl. No.: 19/123,802

(22) PCT Filed: Feb. 22, 2024
(86) PCT No.: PCT/CN2024/078082

§ 371 Date: Apr. 24, 2025

(30) Foreign Application Priority Data
Mar. 9, 2023 (CN) 202310244482.4

(51) Int. Cl. G09G 3/20

(52) U.S. Cl. CPC G09G 3/2092; G09G 2300/0408; G09G 2310/0267; G09G 2310/0286

(57) ABSTRACT

A display panel and a display apparatus. The display panel comprises a base substrate and a second source-drain metal layer. The base substrate has a display area and a non-display area; the non-display area comprises a plurality of sub-areas distributed in an array in both row and column directions; the sub-areas in a same column correspond to shift register units of various stages in a same gate driving circuit; and the sub-areas in a same row correspond to the shift register units of a same stage in the various gate driving circuits. The second source-drain metal layer comprises a plurality of output signal lines. The display panel and the display apparatus can save the occupied space of the gate driving circuits close to the display area in the column direction, thus facilitating the implementation of narrow bezels of display panels.

### CROSS-REFERENCE TO RELATED APPLICATIONS

The present disclosure is the U.S. national phase application of International Application No. PCT/CN 2024/078082, filed on Feb. 22, 2024, which claims priority to the Chinese patent application with application number 202310244482.4, titled “Display Panel and Display Device”, filed on Mar. 9, 2023. The entire contents of these Chinese patent applications are incorporated herein by reference.

### TECHNICAL FIELD

The present disclosure relates to the art of display technology, specifically to a display panel and display device.

### BACKGROUND

Display devices are increasingly pursuing high PPI and narrow bezels. Therefore, the narrow bezel design of GOA layout is particularly important. In related technologies, due to the layout structure of GOA circuits, the panel cannot achieve narrow bezels.

It should be noted that the information disclosed in the background above is only for enhancing the understanding of the background of the present disclosure, and therefore may include information that does not constitute prior art known to those of ordinary skill in the art.

### SUMMARY

The purpose of the present disclosure is to overcome the shortcomings of the existing art and provide a display panel and display device.

According to one aspect of the present disclosure, a display panel, comprising a display area and a non-display area being provided around the display area, wherein the non-display area comprises multiple gate driving circuits, the gate driving circuit comprises multiple shift register units cascaded, and shift register units in each gate driving circuit that provides gate driving signals for sub pixels in a same row is in the same row; the display panel further comprising: a base substrate comprising the display area and the non-display area, and the non-display area comprises multiple sub regions arranged in an array in row and column directions, each sub region in a same column corresponds to a stage of shift register units in a same gate driving circuit, and each sub region in a same row corresponds to a same stage of shift register units of each gate driving circuit; a second source drain metal layer provided on one side of the base substrate, the second source drain metal layer comprising: multiple output signal lines, orthographic projections of the multiple output signal lines on the base substrate extending along a row direction, and the output signal line is arranged corresponding to each of the shift register units; wherein, among multiple output signal lines in a same pixel row, an orthographic projection of a output signal line connected to a shift register unit far away from a display area on the base substrate crosses a sub region corresponding to a shift register unit near a display area, and output signal lines of a same pixel row are separated from each other.

In an exemplary embodiment of the present disclosure, the shift register unit comprises a pull-up node and a pull-down node, the pull-up node is used to control a output transistor connected to it to output a conductive level, and the pull-down node is used to control a output transistor connected to it to output a non-conductive level; wherein, an orthographic projection of a output signal line connected to a shift register unit far away from a display area on the base substrate is separated from orthographic projections of the pull-up node and the pull-down node of a shift register unit close to a display area on the base substrate.

In an exemplary embodiment of the present disclosure, the display panel further comprises: a first conductive layer provided on a side of the base substrate facing the second source drain metal layer, the first conductive layer comprising: a first connection line, an orthographic projection of the first connection line on the base substrate extending along a row direction, the first connection line being used to form the pull-up node; a second connecting line, an orthographic projection of the second connecting line on the base substrate extending along a row direction, the second connecting line being used to form the pull-down node; wherein, orthographic projections of the first and second connection lines of any Nth row of the gate driving circuit close to a display area on the base substrate are between orthographic projections of a Nth row output signal line and a N+1th row output signal line of the gate driving circuit far away from a display area on the base substrate, where N is a natural number.

In an exemplary embodiment of the present disclosure, each gate driving circuit is on a same side of the display area.

In an exemplary embodiment of the present disclosure, at least a portion of the gate driving circuit comprises a first component part and a second component part arranged oppositely on both sides of the display area, a shift register unit of the first component part is connected to some sub pixels of the display area through a first output signal line connected to it, and a shift register unit of the second component part is connected to other sub pixels of the display area through a second output signal line connected to it; wherein, an orthographic projection of any of the first output signal lines on the base substrate and orthographic projections of the pull-up and pull-down nodes of a shift register unit between a first component part and a display area on the base substrate are separated, and an orthographic projection of any of the second output signal lines on the base substrate and orthographic projections of the pull-up and pull-down nodes of a shift register unit between a second component part and a display area on the base substrate are separated.

In an exemplary embodiment of the present disclosure, multiple gate driving circuits comprise a first driving group and a second driving group arranged on both sides of a display area; wherein, among output signal lines of the same driving group, an orthographic projection of a output signal line connected to a shift register unit far away from a display area on the base substrate is separated from orthographic projections of the pull-up node and the pull-down node of a shift register unit close to a display area on the base substrate.

In an exemplary embodiment of the present disclosure, multiple gate driving circuits include at least one first structured gate driving circuit, and each stage shift register unit of the first structured gate driving circuit is connected to multiple output signal lines; wherein, an orthographic projection of any output signal line connected to the first structured gate driving circuit on the base substrate is separated from orthographic projections of the pull-up and pull-down nodes of a shift register unit between the first structured gate driving circuit and display area on the base substrate.

In an exemplary embodiment of the present disclosure, multiple gate driving circuits comprises at least one second structured gate driving circuit, each stage shift register unit of the second structured gate driving circuit comprises first and second sub shift register units arranged oppositely on both sides of a display area, and the first and second sub shift register units respectively provide gate driving signals to sub pixels in a same row through corresponding output signal lines; wherein, an orthographic projection of any output signal line connected to the second structured gate driving circuit on the base substrate is separated from orthographic projections of the pull-up and pull-down nodes of a shift register unit between the second structured gate driving circuit and display area on the base substrate.

In an exemplary embodiment of the present disclosure, the shift register unit further comprises a first transistor and a second transistor, a gate of the first transistor is connected to the pull-up node, a first pole of the first transistor receives a first signal, and a second pole of the first transistor is connected to a output terminal; a gate of the second transistor is connected to the pull-down node; the display panel further comprises: an active layer provided on a side of the base substrate facing the second source drain metal layer, the active layer comprising: multiple first active structures, orthographic projections of the multiple first active structures on the base substrate extending along a column direction and distributed at intervals in a row direction, the first active structure comprising at least a first active portion and second and third active portions connected to both sides of the first active portion in a column direction, the first active portion being used to form a channel region of the first transistor, and the second and third active portions being used to form first and second poles of the first transistor; multiple second active structures, orthographic projections of the multiple second active structures on the base substrate extending along a column direction and distributed at intervals in a row direction, the second active structure comprising at least a fourth active portion and fifth and sixth active portions connected to both sides of the fourth active portion in a column direction, the fourth active portion being used to form a channel region of the second transistor, and the fifth and sixth active portions being used to form first and second poles of the second transistor; the first conductive layer further comprises: a first gate line, an orthographic projection of the first gate line on the base substrate extending along a row direction and covering an orthographic projection of the first active portion on the base substrate, a part structure of the first gate line being used to form a gate of the first transistor, and the first gate line being connected to the first connection line; a second gate line, an orthographic projection of the second gate line on the base substrate extending along a row direction and covering an orthographic projection of the fourth active portion on the base substrate, a part structure of the second gate line being used to form a gate of the second transistor, and the second gate line being connected to the second connection line.

In an exemplary embodiment of the present disclosure, one of the first active structures comprises a first structural portion, a second structural portion, and a third structural portion sequentially connected in a column direction, both the first structural portion and the third structural portion comprise two of the first active portions and one of the third active portions, and the second structural portion comprises one of the second active portions; the first conductive layer comprises four of the first gate lines, and the first connection lines are respectively connected to each of the first gate lines; the display panel further comprises: a first source drain metal layer provided on a side of the first conductive layer facing the second source drain metal layer, the first source drain metal layer comprises: a first transmission line, an orthographic projection of the first transmission line on the base substrate extending along a row direction and on an orthographic projection of the second active portion on the base substrate, the first transmission line is connected to each of the second active portions through a via to output a first signal to the first transistor; a second transmission line for forming the output terminal, an orthographic projection of the second transmission line on the base substrate extending along a row direction and on an orthographic projection of the third active portion on the base substrate, the second transmission lines are respectively connected to corresponding third active portion and output signal line through vias to connect a second pole of the first transistor to an output terminal.

In an exemplary embodiment of the present disclosure, a first pole of the second transistor receives a second signal, and a second pole is connected to an output terminal; one of the second active structures comprises a fourth structural portion, a fifth structural portion, and a sixth structural portion sequentially connected in a column direction, the fourth structural portion and the sixth structural portion each comprise two of the fourth active portions and one of the sixth active portion, and the fifth structural portion comprises one of the fifth active portion; the first conductive layer comprises four of the second gate lines, and the second connection lines are respectively connected to each of the second gate lines; the first source drain metal layer further comprises: a third transmission line, an orthographic projection of the third transmission line on the base substrate extending along a row direction and on an orthographic projection of the fifth active portion on the base substrate, the third transmission line is connected to each of the fifth active portions through a via to output a second signal to the second transistor; a fourth transmission line, an orthographic projection of the fourth transmission line on the base substrate extending along a row direction and on an orthographic projection of the sixth active portion on the base substrate, the fourth transmission line is connected to corresponding sixth active portion and output signal line through vias to connect a second pole of the second transistor to an output terminal.

In an exemplary embodiment of the present disclosure, the shift register unit further comprises a first capacitor and a second capacitor, a first pole of the first capacitor is connected to the pull-up node, and a second pole of the first capacitor is connected to an output terminal; a first pole of the second capacitor is connected to the pull-down node, and a second pole of the second capacitor is connected to an output terminal; wherein, a capacitance value of the first capacitor and a capacitance value of the second capacitor are both greater than or equal to 2 pF.

In an exemplary embodiment of the present disclosure, the second connection line is on a side of the first connection line near a display area; the first conductive layer further comprises: a first conductive portion, which is connected to a side of the first connection line in a row direction near a display area, and is used to form the first pole of the first capacitor; a second conductive portion, which is connected to a side of the second connection line in a row direction near a display area, and is used to form the first pole of the second capacitor; the display panel further comprises: a second conductive layer between the first conductive layer and the second source drain metal layer, wherein the second conductive layer comprises: a third conductive portion, an orthographic projection of the third conductive portion on the base substrate overlaps at least partially with an orthographic projection of the first conductive portion on the base substrate, and the third conductive portion is used to form the second pole of the first capacitor; a fourth conductive portion, an orthographic projection of the fourth conductive portion on the base substrate overlaps at least partially with an orthographic projection of the second conductive portion on the base substrate, and the fourth conductive portion is used to form the second pole of the second capacitor; a first source drain metal layer provided on a side of the second conductive layer facing the second source drain metal layer, and the first source drain metal layer comprises: a fifth conductive portion, an orthographic projection of the fifth conductive portion on the base substrate overlaps at least partially with an orthographic projection of the second conductive portion on the base substrate, and the fifth conductive portion is connected to the first conductive portion through a via; a sixth conductive portion, an orthographic projection of the sixth conductive portion on the base substrate overlaps at least partially with an orthographic projection of the fourth conductive portion on the base substrate, and the sixth conductive portion is connected to the second conductive portion through a via.

In an exemplary embodiment of the present disclosure, the display panel further comprises a second conductive layer, a first source drain metal layer, and a first planarization layer sequentially stacked on a side of the first conductive layer facing the second source drain metal layer; wherein, the thickness of the first planarization layer is inversely proportional to the capacitance values of the first capacitor and the second capacitor.

In an exemplary embodiment of the present disclosure, a thickness of the first planarization layer is greater than or equal to 2000 nm.

In an exemplary embodiment of the present disclosure, the display panel further comprises: an interlayer insulating layer provided between the second conductive layer and the first source drain metal layer; wherein, the ratio of the thickness of the first planarization layer to a thickness of the interlayer insulation layer is greater than or equal to 4.

In an exemplary embodiment of the present disclosure, the display panel further comprises: a first passivation layer, the first passivation layer covers the first planarization layer on a side of the first planarization layer away from the base substrate, and a thickness of the first passivation layer is smaller than the thickness of the first planarization layer.

In an exemplary embodiment of the present disclosure, the shift register unit further comprises a first capacitor and a second capacitor, a first pole of the first capacitor is connected to the pull-up node, and a second pole of the first capacitor is connected to an output terminal; a first pole of the second capacitor is connected to the pull-down node, and a second pole of the second capacitor is connected to an output terminal; the second connection line is provided on a side of the first connection line near a display area; the first conductive layer further comprises: a first conductive portion, which is connected to a side of the first connection line in a row direction near a display area, and is used to form the first pole of the first capacitor; a second conductive portion, which is connected to a side of the second connection line in a row direction near a display area, and is used to form the first pole of the second capacitor; the second conductive layer comprises: a third conductive portion, an orthographic projection of the third conductive portion on the base substrate overlaps at least partially with an orthographic projection of the first conductive portion on the base substrate, and the third conductive portion is used to form the second pole of the first capacitor; a fourth conductive portion, an orthographic projection of the fourth conductive portion on the base substrate overlaps at least partially with an orthographic projection of the second conductive portion on the base substrate, and the fourth conductive portion is used to form the second pole of the second capacitor; the first source drain metal layer comprises: a fifth conductive portion, an orthographic projection of the fifth conductive portion on the base substrate overlaps at least partially with an orthographic projection of the second conductive portion on the base substrate, and the fifth conductive portion is connected to the first conductive portion through a via; a sixth conductive portion, an orthographic projection of the sixth conductive portion on the base substrate overlaps at least partially with an orthographic projection of the fourth conductive portion on the base substrate, and the sixth conductive portion is connected to the second conductive portion through a via; the second source drain metal layer further comprises: a seventh conductive portion, an orthographic projection of the seventh conductive portion on the base substrate overlaps at least partially with an orthographic projection of the fifth conductive portion on the base substrate, and the seventh conductive portion is connected to the third conductive portion through a via; an eighth conductive portion, an orthographic projection of the eighth conductive portion on the base substrate overlaps at least partially with an orthographic projection of the sixth conductive portion on the base substrate, and the eighth conductive portion is connected to the fourth conductive portion through a via; wherein, the first planarization layer is provided with a first hollow portion facing the seventh conductive portion and a second hollow portion facing the eighth conductive portion, the first hollow portion exposes the seventh conductive portion and the second hollow portion exposes the eighth conductive portion.

According to the second aspect of the present disclosure, a display device comprising the display panel as described in any embodiment of the present disclosure.

It should be understood that the above general description and the subsequent detailed description are only exemplary and explanatory, and cannot limit the present disclosure.

### BRIEF DESCRIPTION OF THE DRAWINGS

The accompanying drawings are incorporated into the specification and form a part of the specification, illustrating embodiments in accordance with the present disclosure and used together with the specification to explain the principles of the present disclosure. It is obvious that the figures described below are only some embodiments of the present disclosure, for those skilled in the art, other figures may be obtained based on these figures without creative work.

FIG. 1 is a schematic view of the structure of the display panel according to an embodiment of the present disclosure;

FIG. 2 shows the layout structure of the multi-gates driving circuit GOA in the related art;

FIG. 3 is a circuit diagram of the output circuit of the shift register unit according to an embodiment of the present disclosure;

FIG. 4 is a structural layout of the equivalent circuit of FIG. 3 according to an embodiment of the present disclosure;

FIG. 5 is a structural layout of the pull-up node and the first transistor in FIG. 4;

FIG. 6 is a structural layout of the pull-down node and the second transistor in FIG. 4;

FIG. 7 is a structural layout of the active layer in FIG. 5;

FIG. 8 is a structural layout of the active layer in FIG. 6;

FIG. 9 is a structural layout of the first conductive layer in FIG. 5;

FIG. 10 is a structural layout of the first conductive layer in FIG. 6;

FIG. 11 is a structural layout of the first source drain metal layer in FIG. 5;

FIG. 12 is a structural layout of the first source drain metal layer in FIG. 6;

FIG. 13 is a structural layout of the second source drain metal layer in FIG. 5;

FIG. 14 is a structural layout of the second source drain metal layer in FIG. 6;

FIG. 15 is a stacked layout of the active layer and the first conductive layer in FIG. 5;

FIG. 16 is a stacked layout of the active layer and the first conductive layer in FIG. 6;

FIG. 17 is a stacked layout of the first conductive layer and the second source drain metal layer in FIG. 5;

FIG. 18 is a stacked layout of the first conductive layer and the second source drain metal layer in FIG. 6;

FIG. 19 is a cross-sectional view of the capacitor structure in the shift register unit according to an embodiment of the present disclosure;

FIG. 20 is a cross-sectional view of the capacitor structure in the shift register unit according to another embodiment of the present disclosure;

FIG. 21 is a circuit diagram of some structures of the shift register unit in related art;

FIG. 22 is an improved circuit diagram of the circuit shown in FIG. 21;

FIG. 23 is a schematic view of the layout structure of the gate driving circuit according to another embodiment of the present disclosure;

FIG. 24 is a schematic view of the layout structure of the gate driving circuit according to another embodiment of the present disclosure;

FIG. 25 is a schematic view of the layout structure of the gate driving circuit according to another embodiment of the present disclosure;

FIG. 26 is a schematic view of the layout structure of the gate driving circuit according to another embodiment of the present disclosure.

### DETAILED DESCRIPTION

The example implementation will now be described more comprehensively with reference to the accompanying drawings. However, the example embodiments may be implemented in various forms and should not be understood as limited to the embodiments described herein; on the contrary, providing these implementation makes the present disclosure comprehensive and complete, and fully conveys the concept of example implementation to those skilled in the art. The matching reference numerals in the figure indicate matching or similar structures, therefore their detailed descriptions will be omitted. In addition, the accompanying drawings are only illustrative of the present disclosure and are not necessarily drawn to scale.

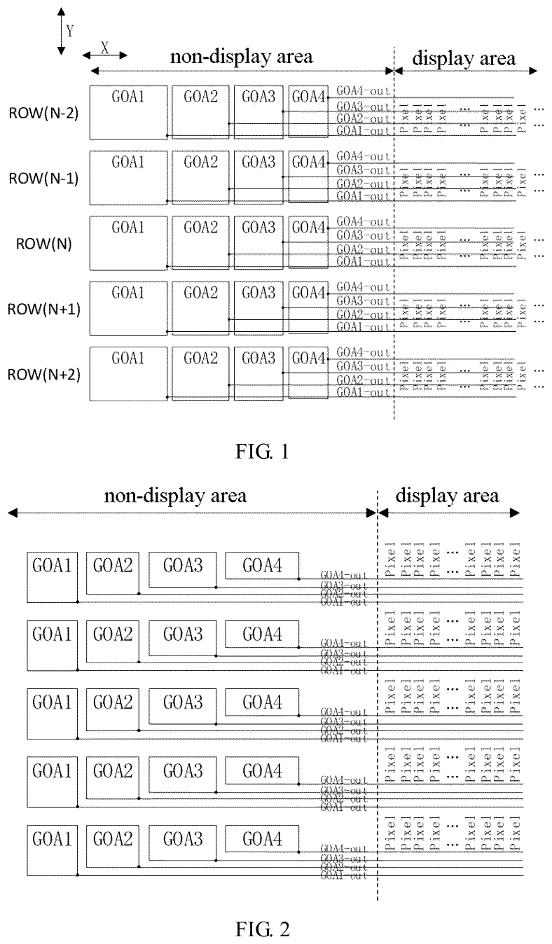

FIG. 1 is a schematic view of the structure of a display panel according to an embodiment of the present disclosure. As shown in FIG. 1, the display panel may include a display area and a non-display area. The non-display area may be provided around the display area, and the non-display area may include multiple gate driving circuits GOA. The gate driving circuit GOA includes multiple cascaded shift register units GOA (n), and shift register units GOA (n) in each gate driving circuit GOA that provides gate driving signals for sub pixels in the same row is in the same row; the display panel may further include a base substrate and a second source drain metal layer SD2. The base substrate has a display area and a non-display area. The non-display area includes multiple sub regions arranged in an array in the row and column direction. Each sub region in the same column corresponds to a stage (level) of the shift register units GOA (n) in the same gate driving circuit GOA, and each sub region in the same row corresponds to the same stage of the shift register unit GOA (n) in each gate driving circuit GOA; The second source drain metal layer SD2 is on one side of the base substrate. The second source drain metal layer SD2 may include multiple output signal lines G-out, the orthographic projection of the multiple output signal lines G-out on the base substrate extend along the row direction X. The output signal lines G-out are arranged corresponding to each shift register unit GOA (n); wherein, among the multiple output signal lines G-out in the same pixel row, the orthographic projection of the output signal line G-out connected to the shift register unit GOA (n) far away from the display area on the base substrate passes through the sub region corresponding to the shift register unit GOA (n) close to the display area, and the output signal lines G-out of the same pixel row are separated from each other.

The display panel provided in the present disclosure includes multiple gate driving circuits GOA, the output signal line G-out of the gate driving circuit GOA is arranged by adding the second source drain metal layer SD2. The output signal line G-out of the gate driving circuit GOA far away from the display overlaps with the coverage area of the gate driving circuit GOA near the display area, that is, the output signal line G-out of the gate driving circuit GOA far away from the display area passes through the area covered by the gate driving circuit GOA near the display area. In this way, the occupied space of the gate driving circuit GOA near the display area in the column direction Y may be saved, thereby avoiding the situation where the column direction Y space is too small and occupies the row direction X space, which is beneficial for achieving narrow bezels and high ppi of the display panel.

The gate driving circuit GOA may be on one side of the display area in the row direction X. The gate driving circuit GOA may be used for row scanning of the display panel. The gate driving circuit GOA usually includes multi-stage shift register units GOA (n), each stage of the shift register unit is cascaded to achieve step-by-step output of row scanning signals. It can be known that the display area of the display panel includes pixel circuits (such as 3T1C, 7T1C, etc.) that correspond one-to-one with the sub pixels. The pixel circuits provide driving current to the sub pixels and drive the sub pixels to emit light. The pixel circuits usually include multiple signal terminals with different functions, each of the signal terminals provides a driving signal according to a certain timing to enable the pixel circuit to output a driving current. The gate driving circuit GOA with different functions is used to provide corresponding gate driving signals to different signal terminals of the pixel circuit, that is, the gate driving circuit GOA outputs gate driving signals according to a certain timing to drive the pixel circuit to provide driving current.

Each stage of the shift register unit GOA (n) in the gate driving circuit GOA of the present disclosure may be distributed stage by stage in the column direction Y and on at least one side of the display area in the row direction X. Moreover, the display panel typically includes multiple gate driving circuits GOA, so that each shift register unit GOA (n) in the multiple gate driving circuits GOA is distributed in an array along the row column direction Y in the non-display area.

The same stage shift register unit GOA (n) in different gate driving circuits GOA may be understood as the shift register unit GOA (n) that provides gate driving signals to different signal terminals in the same pixel circuit. For example, the display panel may include an EM gate driving circuit for providing EM signals and a Reset gate driving circuit for providing reset signals to the pixel circuits. The shift register unit GOA (n) in the EM gate driving circuit that provides EM signals to the nth row pixel circuit and the shift register unit GOA (n) in the Reset gate driving circuit that provides Reset signals to the nth row pixel circuit are the same stage shift register unit GOA (n).

Each sub region in the same column corresponds to each stage of the shift register unit GOA (n) in the same gate driving circuit GOA, and each sub region in the same row corresponds to the same stage shift register unit GOA (n) in each gate driving circuit GOA. Therefore, it is equivalent to one shift register unit GOA (n) corresponding to one sub region. The disclosed sub region may be understood as the area covered by the orthographic projection of the shift register unit GOA (n) on the base substrate. It can be known that the shift register unit GOA (n) usually includes transistors, capacitors, and various signal lines, and the structure that forms the transistors, the structure that forms the capacitors, and the signal lines with different functions are usually distributed in two or more conductive layers. Correspondingly, the sub region corresponding to the shift register unit GOA (n) is the region covered by the orthographic projection of the layer structures of all the transistors, the layer structures of all the capacitors, and the layer structures of all the signal lines in a shift register unit GOA (n) on the base substrate.

The output signal line G-out is in the second source drain metal layer SD2, and the output signal line G-out is the routing of the gate driving signal output from the shift register unit GOA (n). The corresponding setting of the output signal line G-out and the shift register unit GOA (n) in the present disclosure may be that one shift register unit GOA (n) corresponds to one output signal line G-out, and at this time, one shift register unit GOA (n) drives one pixel row; alternatively, one shift register unit GOA (n) may be provided with multiple output signal lines G-out, where one shift register unit GOA (n) drives multiple pixel rows.

The multiple output signal lines G-out in the same pixel row of the present disclosure may be understood as the output signal line G-out that transmit different types of gate driving signals to the same row of pixel circuits. The output signal lines G-out of the same pixel row are separated from each other to avoid signal interference between the output signal lines G-out.

The orthographic projection of output signal line G-out connected to the shift register unit GOA (n) far away from the display area on the base substrate passes through the sub region corresponding to the shift register unit GOA (n) near the display area, that is, the output signal line G-out connected to the shift register unit GOA (n) far away from the display area overlaps with the shift register unit GOA (n) near the display area. Specifically, the output signal line G-out connected to the shift register unit GOA (n) far away from the display area may cross over the sub region where the shift register unit GOA (n) near the display area is located from the second source drain metal layer SD2, that is, from above the sub region where the shift register unit GOA (n) near the display area is located. In this way, the output signal line G-out connected to the shift register unit GOA (n) far away from the display area does not need to occupy additional column direction Y space, which may save column direction Y space for the shift register unit GOA (n) close to the display area. This may fully ensure the column direction Y space of the shift register unit GOA (n) and reduce the row direction X space of the shift register unit GOA (n), thereby enabling the display panel to achieve narrow bezels. Moreover, because the output signal line G-out connected to the gate driving circuit GOA far away from the display area does not occupy additional space in the column direction Y, the disclosed display panel may achieve a high PPI gate driving circuit GOA.

As a comparison, FIG. 2 shows the layout structure of the multi gate driving circuits GOA in the related art. As shown in FIG. 2, when designing multiple sets of GOA side by side, the GOA units near the display area need to reserve output signal lines connected to the GOA units far away from the display area. Therefore, the vertical layout design space of the GOA units near the display area should be smaller than the size of one row of pixels; and the closer the GOA unit is to the display area, the more output signal lines it crosses, resulting in a smaller vertical space in the GOA unit layout; compressing the vertical space will increase the horizontal space, resulting in an increase in bezels and making it impossible for the panel to achieve narrow bezels. Moreover, when there are a large number of GOAs, it may also result in the vertical space of GOA units near the display area being less than the width of one transistor, making it impossible to achieve layout design. Comparing FIG. 1 and FIG. 2, it can be seen that the disclosed display panel is able to save the row direction occupied space of the gate driving circuit compared to the prior art, thereby enabling the panel to achieve narrow bezels.

The following provides a further introduction to the solutions of the present disclosure.

Typically, the shift register unit GOA (n) includes a pull-up node PU and a pull-down node PD. The pull-up node PU may be used to control the output transistor connected to it to output a conductive level, while the pull-down node PD may be used to control the output transistor connected to it to output a non-conductive level. The pull-up node PU controlling the output transistor connected to it to output the conductive level herein may be understood as the pull-up node PU controlling the output transistor connected to it to output a level signal that can turn on the corresponding transistor in the pixel circuit. Similarly, the pull-down node PD controlling the output transistor connected to it to output a non-conductive level may be understood as the pull-down node PD controlling the output transistor connected to it to output a level signal that can turn off the corresponding transistor in the pixel circuit. It should be understood that the conductive level and non-conductive level mentioned herein are related to the type of transistor in the pixel circuit. For example, when the transistor in the pixel circuit connected to the output signal line G-out is an N-type transistor, the pull-up node PU may be specifically used to control the output transistor connected to it to output a high-level signal, and the pull-down node PD may be specifically used to control the output transistor connected to it to output a low-level signal. Alternatively, when the transistor in the pixel circuit is a P-type transistor, the pull-up node PU may be specifically used to control the output transistor connected to it to output a low-level signal, and the pull-down node PD may be specifically used to control the output transistor connected to it to output a high-level signal.

In the layout structure of the disclosed gate driving circuit, the output signal line G-out connected to the shift register unit GOA (n) far away from the display area crosses the sub region corresponding to the shift register unit GOA (n) close to the display area. Each point inside the gate driving circuit GOA has a different signal, and the output signal line G-out also transmits a jump signal. Therefore, there will be capacitive coupling noise between the output signal line G-out and the shift register unit GOA (n) it crosses, especially the pull-up node PU and the pull-down node PD in the shift register unit are more susceptible to interference from capacitive coupling noise, which will affect the signal output of the crossed shift register unit GOA (n) and cause display problems. In response to this problem, the present disclosure further improves the layout structure of the gate driving circuit GOA in the display panel.

As mentioned above, the output signal line G-out connected to the shift register unit GOA (n) far away from the display area needs to cross the shift register near the display area. Based on this, the orthographic projection of the output signal line G-out connected to the shift register unit GOA (n) far away from the display area on the base substrate is separated from the orthographic projections of the pull-up node PU and the pull-down node PD in the shift register unit GOA (n) near the display area on the base substrate, that is, the orthographic projection of the output signal line G-out connected to the shift register unit GOA (n) far away from the display area on the base substrate does not overlap with the orthographic projections of the pull-up node PU and the pull-down node PD in the crossed shift register unit GOA (n) on the base substrate. It is worth noting that in the layout structure, the pull-up node PU and the pull-down node PD are usually traces with a certain extension length. Therefore, in this exemplary embodiment, the output signal line G-out connected to the shift register unit GOA (n) far away from the display area avoids the traces that form the pull-up node PU and the pull-down node PD in the crossed shift register unit GOA (n), respectively. Thus, this exemplary embodiment may reduce the noise interference of the output signal line G-out on the pull-up node PU and pull-down node PD in the crossed shift register unit GOA (n), ensuring that the crossed shift register unit GOA (n) outputs a stable gate driving signal and be able to perform row scanning normally.

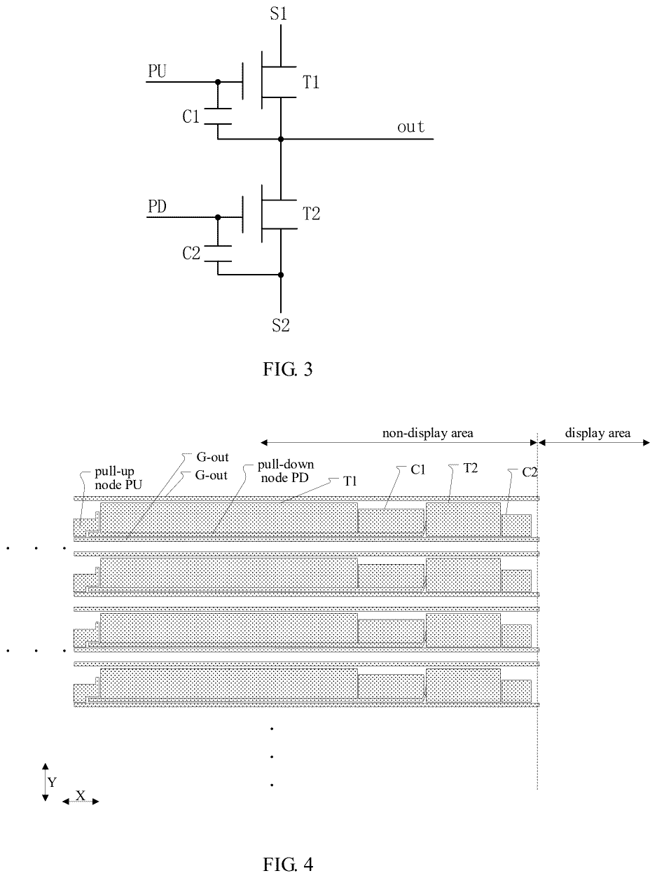

FIG. 3 is a circuit diagram of the output circuit in the shift register unit according to an embodiment of the present disclosure. As shown in FIG. 3, in the exemplary embodiment, the output transistor connected to the pull-up node PU is a first transistor T1, and the output transistor connected to the pull-down node PD is a second transistor T2. The gate of the first transistor T1 is connected to the pull-up node PU, and the first pole receives the first signal S1, while the second pole is connected to the output terminal. The gate of the second transistor T2 is connected to the pull-down node PD, the first pole receives the second signal S2, and the second pole is connected to the output terminal. Wherein, both the first signal S1 and the second signal S2 may be DC signals, or the first signal S1 may be a clock signal provided by the clock signal line, the second signal S2 may be a DC signal provided by the power line. The polarity of the first signal S1 may be opposite to that of the second signal S2, that is, when the first signal S1 is at a high level, the second signal S2 is at a low level; alternatively, when the first signal S1 is at a low level, the second signal S2 is at a high level. When the pull-up node PU is at a conductive level (such as a high level), the pull-up node PU may control the first transistor T1 to conduct, and transmit the first signal S1 received by the first pole to the output terminal, so that the shift register unit GOA (n) outputs a high-level signal to achieve shift output. When the pull-down node PD is at a conductive level (such as a high level), the pull-down node PD may control the second transistor T2 to conduct. The conducting second transistor T2 transmits the second signal S2 received by the first terminal to the output terminal, causing the shift register unit GOA (n) to output a low-level signal. Of course, the above-mentioned conductive level may also be a low level. The following is only an example of the circuit structure shown in FIG. 3 to further explain the solution of the present disclosure.

The display panel of the present disclosure may include the base substrate and an active layer ACT, a first conductive layer Gate1, a second conductive layer Gate2, a first source drain metal layer SD1, and a second source drain metal layer SD2 sequentially stacked on one side of the base substrate. An insulating layer may be provided between the functional layers.

FIG. 4 is a structural layout of the equivalent circuit of FIG. 3 according to an embodiment of the present disclosure. As shown in FIG. 4, the figure shows a schematic view of the structure of the region where the pull-up node PU, the pull-down node PD, the first transistor T1, the second transistor T2, the first capacitor C1, and the second capacitor C2 are in the shift register unit close to the display area and the output signal line G-out connected to the shift register unit far away from the display area. The output signal line G-out in the figure is the output signal line connected to the gate driving circuit GOA far away from the display area. It can be seen that the output signal line G-out connected to the shift register unit far away from the display area crosses the sub region of the shift register unit close to the display area and avoids the pull-up node PU and the pull-down node PD in the crossed shift register unit. In addition, within the same shift register unit, the first transistor T1, the first capacitor C1, the second transistor T2, and the second capacitor C2 are on one side of the display area from far to near. Both the orthographic projections of the pull-up node PU and the pull-down node PD on the base substrate extend along the row direction.

It should be understood that the structure A described in the present disclosure extends along the B direction, which means that A may include a main part and a secondary part connected to the main part. The main part is a line, line segment, or strip-shaped body, and the main part extends along the B direction, with the length of the main part extending along the B direction being greater than the length of the secondary part extending in other directions.

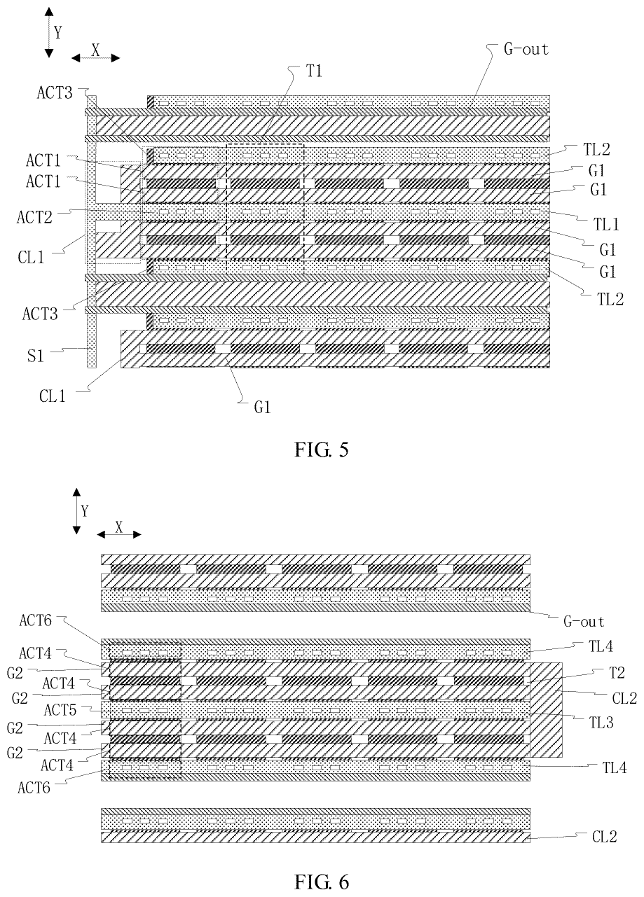

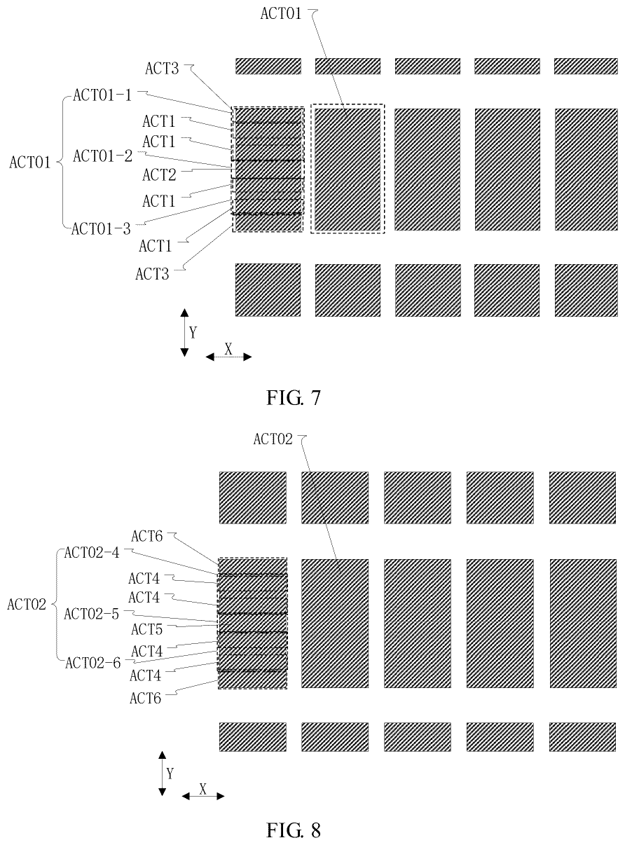

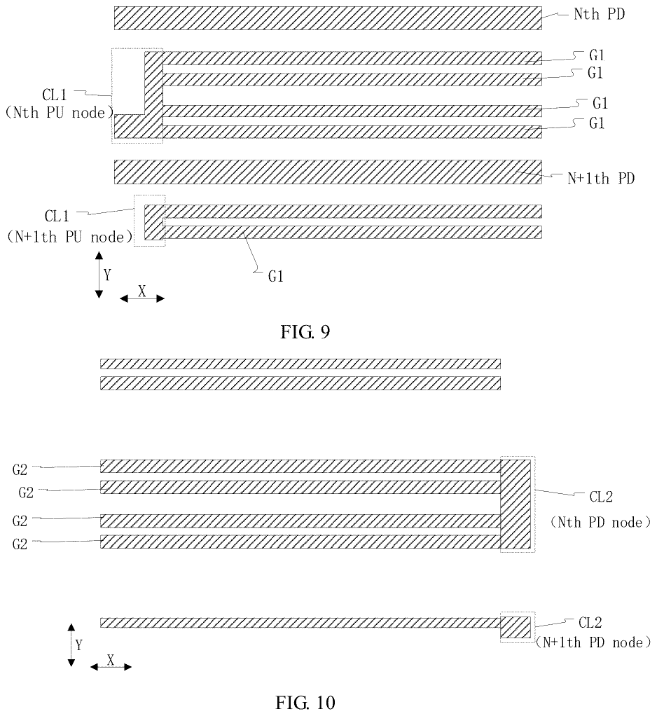

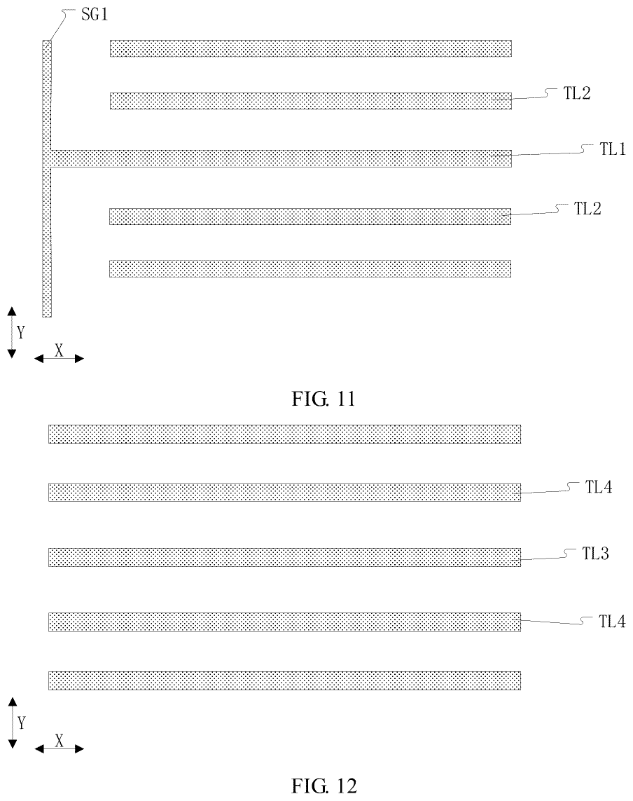

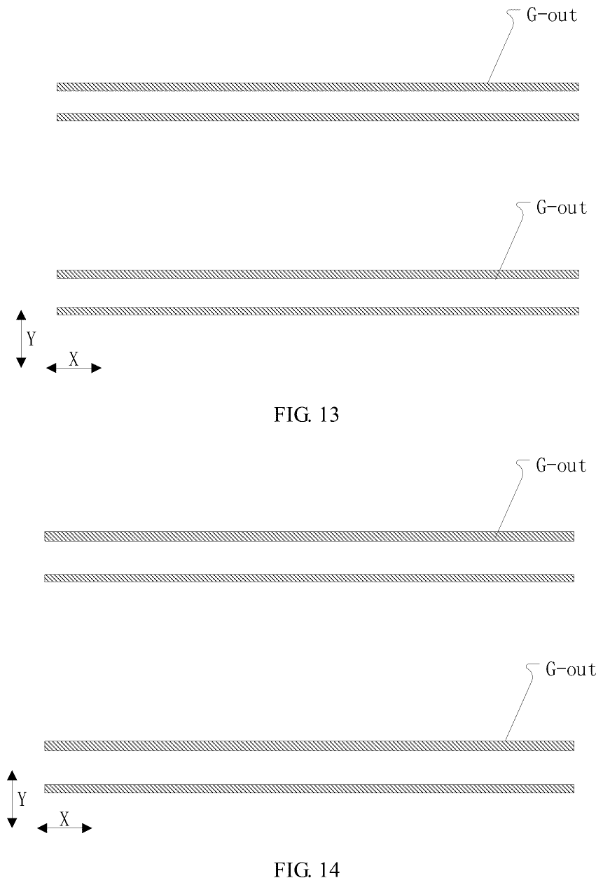

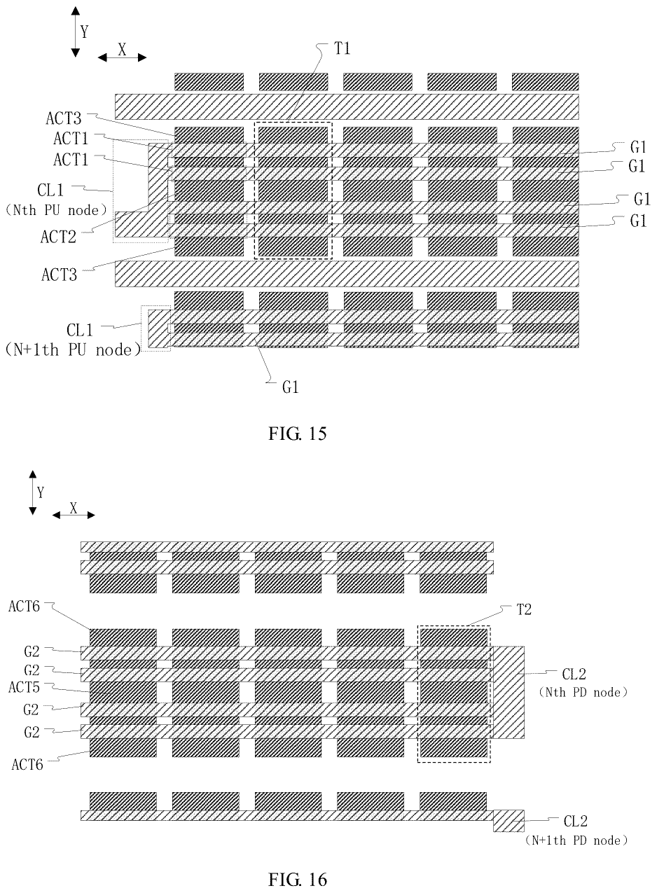

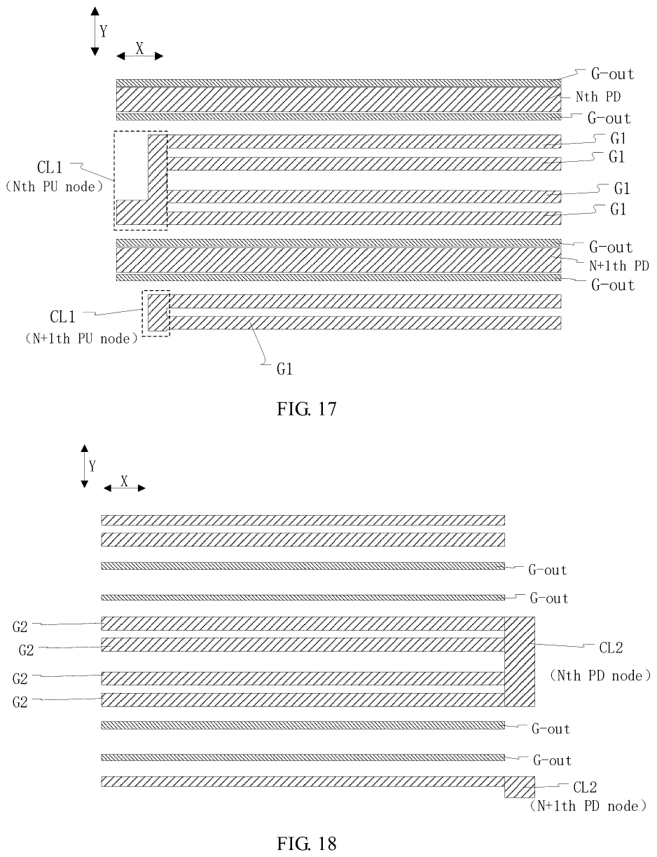

FIG. 5 shows the structural layout of the pull-up node and the first transistor in FIG. 4, FIG. 6 shows the structural layout of the pull-down node and the second transistor in FIG. 4, FIG. 7 shows the structural layout of the active layer in FIG. 5, FIG. 8 shows the structural layout of the active layer in FIG. 6, FIG. 9 shows the structural layout of the first conductive layer in FIG. 5, FIG. 10 shows the structural layout of the first conductive layer in FIG. 6, FIG. 11 shows the structural layout of the first source drain metal layer in FIG. 5, FIG. 12 shows the structural layout of the first source drain metal layer in FIG. 6, FIG. 13 shows the structural layout of the second source drain metal layer in FIG. 5, FIG. 14 shows the structural layout of the second source drain metal layer in FIG. 6, FIG. 15 shows the stacked layout of the active layer and the first conductive layer in FIG. 5, FIG. 16 is the stacked layout of the active layer and the first conductive layer in FIG. 6, and FIG. 17 is the stacked layout of the first conductive layer and the second source drain metal layer in FIG. 5, FIG. 18 shows the stacked layout of the first conductive layer and the second source drain metal layer in FIG. 6.

As shown in FIGS. 5, 7, and 15, in the exemplary embodiment, the active layer ACT may include multiple first active structures ACT01 and multiple second active structures ACT02. The orthographic projection of the multiple first active structures ACT01 on the base substrate extend along the column direction Y and are spaced apart in the row direction X. The first active structure ACT01 includes at least a first active portion ACT1 and a second active portion ACT2 and a third active portion ACT3 connected to both sides of the first active portion ACT1 in the column direction Y. The first active portion ACT1 is used to form the channel region of the first transistor T1, and the second active portion ACT2 and third active portion ACT3 are used to form the first and second poles of the first transistor T1.

Continuing to refer to FIGS. 5, 7, and 15, in an exemplary embodiment, one first active structure ACT01 may include a first structural portion ACT01-1, a second structural portion ACT01-2, and a third structural portion ACT01-3 sequentially connected in the column direction Y. Each of the first structural portion ACT01-1 and the third structural portion ACT01-3 may include two first active portions ACT1 and one third active portion ACT3, and the second structural portion ACT01-2 may include one second active portion ACT2; correspondingly, the first conductive layer Gate1 may include four first gate lines G1, and the first connection lines CL1 are respectively connected to each first gate line G1. In this way, multiple parallel small transistors are formed through the active layer ACT and the first conductive layer Gate1, and the multiple parallel small transistors constitute the first transistor T1 in FIG. 3.

As shown in FIGS. 6, 8, and 16, in the exemplary embodiment, the orthographic projection of multiple second active structures ACT02 on the base substrate extend along the column direction Y and are spaced apart in the row direction X. The second active structure ACT02 includes at least a fourth active portion ACT4 and a fifth active portion ACT5 and a sixth active portion ACT6 connected to both sides of the fourth active portion ACT4 in the column direction Y. The fourth active portion ACT4 is used to form the channel region of the second transistor T2, and the fifth and sixth active portions ACT5 and ACT6 are used to form the first and second poles of the second transistor T2.

Continuing to refer to FIGS. 6, 8, and 16, in the exemplary embodiment, one second active structure ACT02 includes a fourth structural portion ACT02-4, a fifth structural portion ACT02-5, and a sixth structural portion ACT02-6 sequentially connected in the column direction Y. The fourth structural portion ACT02-4 and the sixth structural portion ACT02-6 each include two fourth active portions ACT4 and one sixth active portion ACT6, and the fifth structural portion ACT02-5 includes one fifth active portion ACT5; correspondingly, the first conductive layer Gate1 includes four second gate lines G2, and the second connection lines CL2 are respectively connected to each second gate line G2. In this way, multiple parallel small transistors are formed through the active layer ACT and the first conductive layer Gate1, and the multiple parallel small transistors constitute the second transistor T2 shown in FIG. 3.

As shown in FIGS. 5, 9, and 15, in the exemplary embodiment, the first conductive layer Gate1 may include the first gate line G1, the first connection line CL1, the second gate line G2, and the second connection line CL2. The first connection line CL1 may be used to form the pull-up node PU in FIG. 3, and the second connection line CL2 may be used to form the pull-down node PD in FIG. 3. It is worth noting that in this exemplary embodiment, only a partial layout structure of the shift register unit is shown in the figure. In the complete layout structure, the orthographic projection of the first connection line CL1 on the base substrate and the orthographic projection of the second connection line CL2 on the base substrate are both traces extending along the row direction X. In addition, in the equivalent circuit of the shift register unit, the pull-down node PD is further connected to other devices. Therefore, the partial structure of the second connection line CL2 that forms the pull-down node PD passes through the region corresponding to the first transistor T1, as shown in FIG. 9, the partial structure of the second connection line CL2 in the region corresponding to the first transistor T1 is between adjacent two rows of the first gate lines G1.

The orthographic projection of the first gate line G1 on the base substrate extends along the row direction X and covers the orthographic projection of the first active portion ACT1 on the base substrate. Part of the structure of the first gate line G1 is used to form the gate of the first transistor T1, and the first gate line G1 is connected to the first connection line CL1 to connect the gate of the first transistor T1 to the pull-up node PU. The orthographic projection of the second gate line G2 on the base substrate extends along the row direction X and covers the fourth active portion ACT4. Part of the structure of the second gate line G2 is used to form the gate of the second transistor T2, and the second gate line G2 is connected to the second connection line CL2 to connect the gate of the second transistor T2 to the pull-down node PD.

As shown in FIGS. 5 and 11, in the exemplary embodiment, the first source drain metal layer SD1 may include first to fourth transmission lines TL1 to TL4, wherein the orthographic projection of the first transmission line TL1 on the base substrate extends along the row direction X in the front projection of the substrate and is on the orthographic projection of the second active portion ACT2 on the base substrate. The first transmission line TL1 is connected to each second active portion ACT2 through a via to output the first signal S1 to the first transistor T1; the second transmission line TL2 may be used to form the output terminal. The orthographic projection of the second transmission line TL2 on the base substrate extends along the row direction X and is on the orthographic projection of the third active portion ACT3. The second transmission line TL2 may be connected to its corresponding third active portion ACT3 and output signal line G-out through a via to connect the second pole of the first transistor T1 to the output terminal.

As shown in FIG. 11, in the exemplary embodiment, the first source drain metal layer SD1 may further include multiple first signal lines SG1, the orthographic projection of the multiple first signal lines SG1 on the base substrate extend along the column direction Y and are spaced apart in the row direction X. The first signal line SG1 is used to transmit the first signal S1, and the first signal line SG1 is set in one-to-one correspondence with the first transmission line TL1, thereby outputting the first signal S1 to the first transmission line TL1.

As shown in FIGS. 6 and 12, in the exemplary embodiment, the orthographic projection of the third transmission line TL3 on the base substrate extends along the row direction X and is on the orthographic projection of the fifth active portion ACT5 on the base substrate. The third transmission line TL3 is connected to each fifth active portion ACT5 through a via to output the second signal S2 to the second transistor T2; the orthographic projection of the fourth transmission line TL4 on the base substrate extends along the row direction X and is on the orthographic projection of the sixth active portion ACT6 on the base substrate. The fourth transmission line TL4 may be connected to its corresponding sixth active portion ACT6 and output signal line G-out through a via to connect the second pole of the second transistor T2 to the output terminal.

In addition, the first source drain metal layer SD1 may further include multiple second signal lines (not shown in the figure), the orthographic projection of the multiple second signal lines on the base substrate may extend along the column direction Y and be spaced apart in the row direction X. The second signal line is used to transmit the second signal S2, and the second signal line is arranged in one-to-one correspondence with the third transmission line TL3, thereby outputting the second signal S2 to the third transmission line TL3.

As shown in FIGS. 13 and 14, the second source drain metal layer SD2 may include multiple output signal lines G-out. The output signal lines G-out may be connected to the second transmission line TL2 and the fourth transmission line TL4 in the shift register unit GOA (n) through vias to connect with the output terminal of the shift register unit GOA (n) to be connected.

In the complete layout structure, the structure forming the first transistor T1 and the structure forming the second transistor T2 may be spaced apart in the row direction X, so that the output signal line G-out connecting the shift register unit GOA (n) may be connected to the second transmission line TL2 through a via at the position corresponding to the second transmission line TL2, and to the fourth transmission line TL4 through a via at the position corresponding to the fourth transmission line TL4.

As shown in FIG. 3, each shift register unit GOA (n) may further include the first capacitor C1 and the second capacitor C2. The first pole of the first capacitor C1 is connected to the pull-up node PU, and the second pole is connected to the output terminal; the first pole of the second capacitor C2 is connected to the pull-down node PD, and the second pole is connected to the output terminal. Wherein, the first capacitor C1 may use the signal from the output terminal to perform potential bootstrap on the pull-up node PU, and the first capacitor C1 may control the pull-up node PU to maintain a stable potential. Therefore, increasing the capacitance of the first capacitor C1 may improve the anti-interference performance of the pull-up node PU. Similarly, the second capacitor C2 may use its stored charge to stabilize the voltage of the pull-down node PD, maintaining the potential of the pull-down node PD stability. Therefore, increasing the capacitance of the second capacitor C2 may enhance the anti-interference ability of the pull-down node PD.

In the exemplary embodiment, the capacitance values of the first capacitor C1 and the second capacitor C2 may both be greater than or equal to 2 pF, such as 2 pF, 2.5 pF, 3 pF, 3.5 pF, 4 pF, etc. In the prior art, the capacitance values of the first capacitor C1 and the second capacitor C2 are usually 0.5 pF. Compared with the prior art, the capacitance values of the first capacitor C1 and the second capacitor C2 in this exemplary embodiment are greatly improved, which may reduce the noise interference of the output signal line G-out on the pull-up node PU and the pull-down node PD in the crossed shift register unit GOA (n).

In addition, it should be understood that in the layout structure, capacitance coupling noise is inevitably generated between adjacent metal traces. Therefore, when setting the capacitance values of the first capacitor C1 and the second capacitor C2 in the present disclosure, it is necessary to fully consider the influence of capacitance coupling noise between traces, so that the capacitance values of the first capacitor C1 and the second capacitor C2 are large enough to cover these capacitance coupling noises.

The structure of the first capacitor C1 and the second capacitor C2 in FIG. 3 will be further introduced in conjunction with the accompanying drawings.

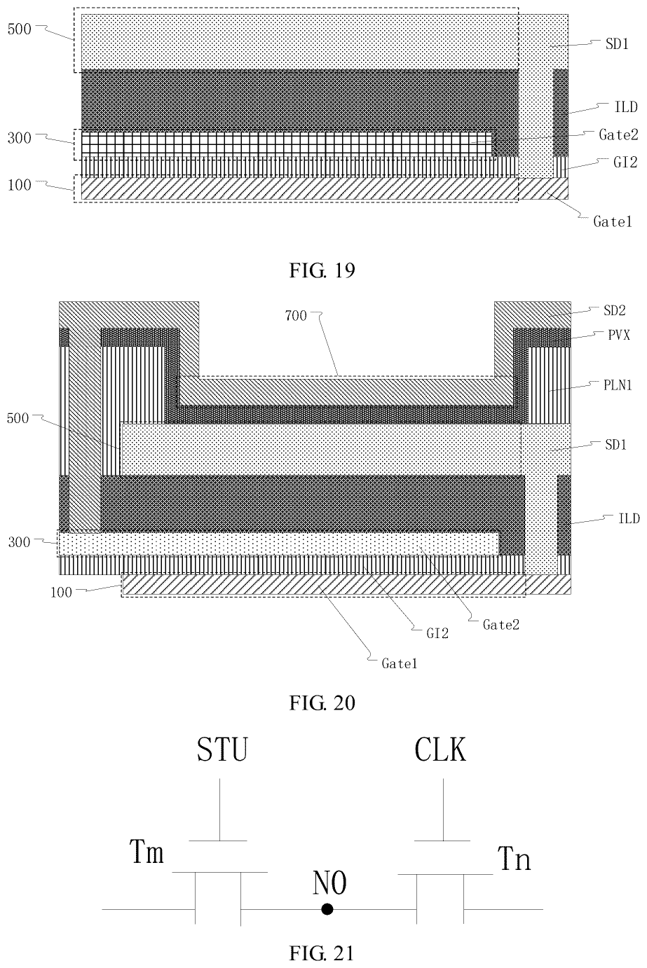

FIG. 19 is a cross-sectional view of the capacitor structure in a shift register unit according to an embodiment of the present disclosure. As shown in FIG. 19, the first conductive layer Gate1 may further include a first conductive portion 100. The first conductive portion 100 is connected to one side of the first connection line CL1 near the display area in the row direction X. The first conductive portion 100 is used to form the first pole of the first capacitor C1. The second conductive layer Gate2 may further include a third conductive portion 300. The orthographic projection of the third conductive portion 300 on the base substrate overlaps at least partially with the orthographic projection of the first conductive portion 100 on the base substrate. The third conductive portion 300 is used to form the second pole of the first capacitor C1; the first source drain metal layer SD1 may further include a fifth conductive portion 500. The orthographic projection of the fifth conductive portion 500 on the base substrate overlaps at least with the orthographic projection of the second conductive portion on the base substrate. The fifth conductive portion 500 is connected to the first conductive portion 100 through a via.

Wherein, the orthographic projections of the first conductive portion 100 and the third conductive portion 300 on the base substrate at least partially overlap, that is, there is an overlap portion between the first conductive portion 100 and the third conductive portion 300 in the thickness direction of the base substrate, so that the first conductive portion 100 and the third conductive portion 300 form the first capacitor structure through the overlap portion. Similarly, the fifth conductive portion 500 overlaps with the third conductive portion 300 to form the second capacitor structure, and the fifth conductive portion 500 is connected to the first conductive portion 100 through a via, so that the first capacitor structure and the second capacitor structure are connected in parallel to form the first capacitor C1, making the first capacitor C1 have a “sandwich structure”, which may increase the capacitance of the first capacitor C1. It can be understood that as the capacitance of the first capacitor C1 increases, the voltage stabilization of the first capacitor C1 on the pull-up node PU is enhanced, thereby improving the anti-interference performance of the pull-up node PU, that is, reducing the noise interference of the output signal line G-out on the pull-up node PU in the crossed shift register unit GOA (n).

It should be understood that the three-layer structure shown in FIG. 19 to increase the first capacitor structure may also be applied to the second capacitor C2. For example, the first conductive layer Gate1 may further include the second conductive portion. The second conductive portion is connected to one side of the second connection line CL2 near the display area in the row direction X. The second conductive portion is used to form the first pole of the second capacitor C2; the second conductive layer Gate2 may further include a fourth conductive portion. The orthographic projection of the fourth conductive portion on the base substrate overlaps at least partially with the orthographic projection of the second conductive portion on the base substrate. The fourth conductive portion is used to form the second pole of the second capacitor C2; the first source drain metal layer SD1 may further include a sixth conductive portion. The orthographic projection of the sixth conductive portion on the base substrate overlaps at least with the orthographic projection of the fourth conductive portion on the base substrate. The sixth conductive portion is connected to the second conductive portion through a via. Similarly, the second conductive portion overlaps with the fourth conductive portion to form a third capacitor structure, the sixth conductive portion overlaps with the fourth conductive portion to form a fourth capacitor structure, and the sixth conductive portion is connected to the second conductive portion through a via, so that the first capacitor structure and the second capacitor structure are connected in parallel to form the second capacitor C2. This may increase the capacitance of the second capacitor C2, and the increased capacitance of the second capacitor C2 may reduce the noise interference of the output signal line G-out on the pull-down node PD in the crossed shift register unit GOA (n).

In some embodiments of the present disclosure, the two conductive portions forming the capacitor structure may completely overlap. For example, the first conductive portion 100 and the third conductive portion 300 may completely overlap, for example, the orthographic projection of one of the first conductive portion 100 and the third conductive portion 300 on the base substrate may cover the orthographic projection of the other on the base substrate, which may maximize the capacitance value formed by these two conductive portions. And the structure may also be applied to capacitor structures formed by other conductive portions, thereby further increasing the capacitance values of the first capacitor C1 and the second capacitor C2.

It can be seen that in this exemplary embodiment, by adding the fifth conductive portion 500 and the sixth conductive portion to the first source drain metal layer SD1, the capacitance values of the first capacitor C1 and the second capacitor C2 may be increased, thereby reducing the noise interference of the output signal line G-out on the pull-up node PU and the pull-down node PD in the crossed shift register unit GOA (n).

FIG. 20 is a cross-sectional view of the capacitor structure in the shift register unit according to another embodiment of the present disclosure. As shown in FIG. 20, in this exemplary embodiment, the first conductive layer Gate1 may include the first conductive portion 100 and the second conductive portion. The first conductive portion 100 is connected to the side of the first connection line CL1 near the display area in the row direction X. The first conductive portion 100 is used to form the first pole of the first capacitor C1; the second conductive layer Gate2 may include the third conductive portion 300. The orthographic projection of the third conductive portion 300 on the base substrate overlaps at least partially with the orthographic projection of the first conductive portion 100 on the base substrate. The third conductive portion 300 is used to form the second pole of the first capacitor C1; the first source drain metal layer SD1 may include the fifth conductive portion 500. The orthographic projection of the fifth conductive portion 500 on the base substrate overlaps at least with the orthographic projection of the second conductive portion on the base substrate. The fifth conductive portion 500 is connected to the first conductive portion 100 through a via; the second source drain metal layer SD2 may include a seventh conductive portion 700. The orthographic projection of the seventh conductive portion 700 on the base substrate overlaps at least partially with the orthographic projection of the fifth conductive portion 500 on the base substrate. The seventh conductive portion 700 is connected to the third conductive portion 300 through a via.

Wherein, the first conductive layer Gate1, the second conductive layer Gate2, and the first source drain metal layer SD1 may have all the features shown in FIG. 19. Based on this, compared with the capacitor structure shown in FIG. 19, the present exemplary embodiment forms a fifth capacitor structure by a seventh conductive portion 700 adding to the second source drain metal layer SD2 and the fifth conductive portion 500 of the first source drain metal layer SD1. The seventh conductive portion 700 is connected to the third conductive portion 300 through a via, so that the fifth capacitor structure, the first capacitor structure, and the second capacitor structure are connected in parallel to form the first capacitor C1, further increasing the capacitance value of the first capacitor C1.

It is worth noting that in the present exemplary embodiment, there is further an insulating layer between the first source drain metal layer SD1 and the second source drain metal layer SD2. The insulating layer may include a first planarization layer PLN1. The thickness of the first planarization layer PLN1 is relatively thick. In order to reduce the insulation between the seventh conductive portion 700 and the fifth conductive portion 500, the present exemplary embodiment may provide a first hollow portion on the first planarization layer PLN1, the first hollow portion faces the seventh conductive portion 700 in the thickness direction of the base substrate, so that the seventh conductive portion 700 may be exposed through the first hollow portion, and the seventh conductive portion 700 is able to form the fifth capacitor structure with the fifth conductive portion 500.

Similarly, the first conductive layer Gate1 may further include the second conductive portion, the second conductive portion is used to form the first pole of the second capacitor C2; the second conductive layer Gate2 may further include the fourth conductive portion, the orthographic projection of the fourth conductive portion on the base substrate overlaps at least partially with the orthographic projection of the second conductive portion on the base substrate. The fourth conductive portion is used to form the second pole of the second capacitor C2; the first source drain metal layer SD1 may include the sixth conductive portion, the orthographic projection of the sixth conductive portion on the base substrate overlaps at least with the orthographic projection of the fourth conductive portion on the base substrate. The sixth conductive portion is connected to the second conductive portion through a via; the second source drain metal layer SD2 may include an eighth conductive portion, the orthographic projection of the eighth conductive portion on the base substrate overlaps at least partially with the orthographic projection of the sixth conductive portion on the base substrate. The eighth conductive portion is connected to the fourth conductive portion through a via. In this way, the eighth conductive portion is added to the second source drain metal layer SD2 to form the sixth capacitor structure with the sixth conductive portion of the first source drain metal layer SD1. The eighth conductive portion is connected to the fourth conductive portion through a via, so that the sixth capacitor structure, the third capacitor structure, and the fourth capacitor structure are connected in parallel to form the second capacitor C2, further increasing the capacitance of the second capacitor C2. Similarly, a second hollow portion is further provided on the first planarization layer PLN1, the second hollow portion faces the eighth conductive portion in the thickness direction of the base substrate, so that the eighth conductive portion may be exposed through the second hollow portion, enabling the eighth conductive portion to form the sixth capacitor structure with the sixth conductive portion.

Continuing to refer to FIG. 20, in an exemplary embodiment, the display panel may further include the first planarization layer PLN1 between the first source drain metal layer SD1 and the second source drain metal layer SD2, and the thickness of the first planarization layer PLN1 may be inversely proportional to the capacitance values of the first capacitor C1 and the second capacitor C2. Specifically, when the capacitance of the first capacitor Cl is small, the first capacitor C1 has a relatively small effect on maintaining the potential stability of the pull-up node PU. At this time, the pull-up node PU is more susceptible to noise interference from the output signal line G-out above it. Therefore, the thickness of the first planarization layer PLN1 may be increased. By increasing the thickness of the first planarization layer PLN1, the insulation effect between the first source drain metal layer SD1 and the second source drain metal layer SD2 may be improved, thereby weakening the noise interference of the output signal line G-out on the pull-up node PU and the pull-down node PD in the crossed shift register unit GOA (n). When the capacitance of the first capacitor C1 is large, the first capacitor C1 has a strong voltage stabilization effect on the pull-up node PU. At this time, the pull-up node PU is less susceptible to noise interference from the output signal line G-out above it. Therefore, the thickness of the first planarization layer PLN1 may be correspondingly reduced.

Similarly, the thickness of the first planarization layer PLN1 has a similar relationship with the capacitance of the second capacitor C2.

It is worth noting that in this exemplary embodiment, the thickness of the first planarization layer PLN1 may not be uniform. For example, the thickness of the first planarization layer PLN1 at a position corresponding to the pull-up node PU may be set according to the capacitance value of the first capacitor C1, and the thickness of the first planarization layer PLN1 at a position corresponding to the pull-down node PD may be set according to the capacitance value of the second capacitor C2, so that the first planarization layer PLN1 can not only improve the anti-interference ability of the pull-up node PU but also improve the anti-interference ability of the pull-down node PD, reducing the noise interference received by the pull-up node PU and the pull-down node PD.

In an exemplary embodiment, the thickness of the first planarization layer PLN1 is greater than or equal to 2000 nm, such as 2000 nm, 2500 nm, 3000 nm, etc. In this exemplary embodiment, the first planarization layer PLN1 may be made using organic materials. Compared to inorganic materials, organic materials have better toughness, which is conducive to forming a thicker first planarization layer PLN1.

As shown in FIG. 20, in an exemplary embodiment, the display panel may further include an interlayer insulating layer (ILD) between the second conductive layer Gate2 and the first source drain metal layer SD1. The ratio of the thickness of the first planarization layer PLN1 to the thickness of the interlayer insulating layer (ILD) may be greater than or equal to 4, such as 4, 5, 6, 7, etc. For example, the thickness of the interlayer insulating layer ILD may be 500 nm, and the thickness of the first planarization layer PLN1 may be greater than or equal to 2000 nm. The present exemplary embodiment may determine the thickness of the first planarization layer PLN1 based on the above proportional relationship after determining the thickness of the interlayer insulating layer ILD, in order to achieve the goal of increasing the thickness of the first planarization layer PLN1.

As shown in FIG. 20, in an exemplary embodiment, the display panel may further include a first passivation layer PVX1, the first passivation layer PVX1 covers the first planarization layer PLN1 on the side of the first planarization layer PLN1 facing away from the base substrate. The thickness of the first passivation layer PVX1 is smaller than that of the first planarization layer PLN1. For example, the first passivation layer PVX1 may be made using inorganic materials with a thickness of 150 nm. By adding the first passivation layer PVX1, the insulating layer thickness between the first source drain metal layer SD1 and the second source drain metal layer SD2 may be further increased, further reducing the noise interference of the output signal line G-out on the pull-up node PU and pull-down node PD in the crossed shift register unit GOA (n).

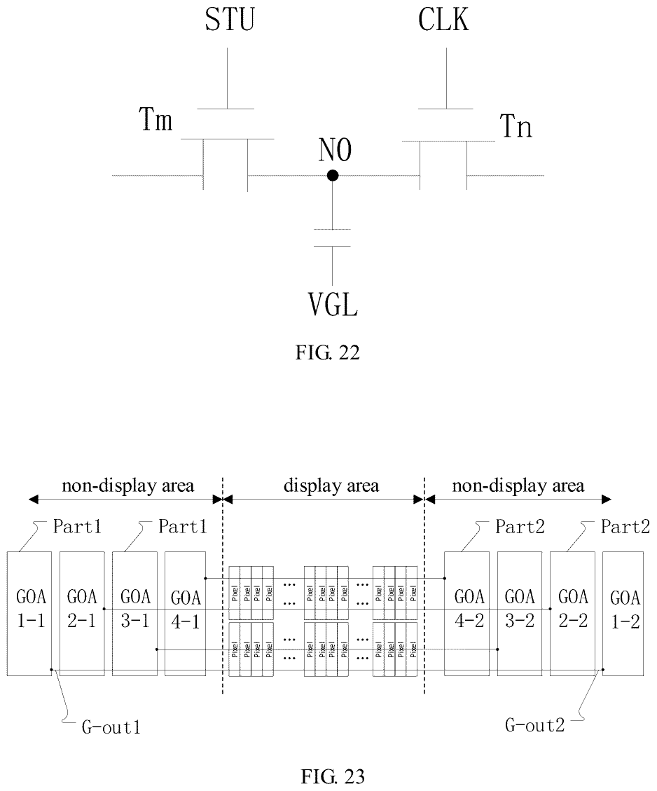

In addition, it is worth noting that in some embodiments, there are other noise prone points in the shift register unit, that is, other nodes that are easily affected by noise interference. For example, FIG. 21 is a circuit diagram of some structures of the shift register unit in related art, and FIG. 22 is an improved circuit diagram of the circuit shown in FIG. 21. As shown in FIG. 21, when the signal terminal STU outputs a low-level signal, the transistor Tm is turned off, and the node NO is floating, which is easily affected by noise interference such as coupling capacitance. Regarding this issue, as shown in FIG. 22, this exemplary embodiment may add a capacitor CO at node NO to maintain the stable potential of node NO, thereby improving the anti-noise interference of noise prone points of the shift register unit. And it should be understood that the capacitance value of capacitor CO may be increased by increasing the overlapping area, or the structure shown in FIG. 19 or FIG. 20 may be used to increase the capacitance value of capacitor CO, which will not be described in detail herein.

The wiring structure of the output signal line G-out connected to the gate driving circuit GOA far away from the display area crossing the gate driving circuit GOA close to the display area, may be applied to various different layout structures of the gate driving circuit GOA. Further explanation will be provided below in conjunction with the accompanying drawings.

As shown in FIG. 1, multiple gate driving circuits GOA may be on the same side of the display area. In such structure, the gate driving circuits GOA adopt a single-sided driving mode, that is, each gate driving circuit GOA provides gate driving signals from the same side of the display area to the pixel circuits in the display area.

FIG. 23 is a schematic view of the layout structure of the gate driving circuit according to another embodiment of the present disclosure. In the figure, GOA1 represents the first gate driving circuit, GOA2 represents the second gate driving circuit, and so on. As shown in FIG. 23, in the exemplary embodiment, at least a portion of the gate driving circuit GOA includes a first component part Part1 and a second component part Part2 arranged oppositely on both sides of the display area. The shift register unit GOA (n) in the first component part Part1 is connected to some sub pixels in the display area through the first output signal line G-out1 connected to the shift register unit GOA (n), and the shift register unit GOA (n) in the second component part Part2 is connected to other sub pixels in the display area through the second output signal line G-out2 connected to the shift register unit GOA (n); wherein, the orthographic projection of any first output signal line G-out1 on the base substrate are separated from the orthographic projections of the pull-up node PU and the pull-down node PD of the shift register unit GOA (n) between the first component part Part1 and the display area on the base substrate, and the orthographic projection of any second output signal line G-out2 on the base substrate are separated from the orthographic projections of the pull-up node PU and the pull-down node PD of the shift register unit GOA (n) between the second component part Part2 and the display area on the base substrate.

In the present exemplary embodiment, the gate driving circuit GOA includes the first component part Part1 and the second component part Part2 arranged oppositely on both sides of the display area. The first component part Part1 drives some sub pixels from one side of the display area, and the second component part Part2 drives some sub pixels from the other side of the display area. Therefore, the gate driving circuit GOA provides gate control signals from both sides of the display area for bilateral driving. As mentioned above, the display area includes pixel circuits that correspond one-to-one with the sub pixels. The output line connecting some sub pixels of the display area described in the present disclosure may be understood as connecting the output line to the pixel circuit corresponding to the said some sub pixels, and driving the corresponding sub pixel through the pixel circuit.

For example, as shown in FIG. 23, multiple gate driving circuits include the second gate driving circuit GOA2, the second gate driving circuit GOA2 includes a first component part GOA2-1 and a second component part GOA2-2 arranged on both sides of the display area.

It is worth noting that in this exemplary embodiment, as shown in FIG. 23, all gate driving circuits GOA are double-sided driven, that is, all gate driving circuits GOA include the first and second component parts Part1 and Part2 that are arranged oppositely on both sides of the display area. Alternatively, some of the gate driving circuits GOA may be double-sided driven, while other gate driving circuits GOA may be single-sided driven.

In this structure, the orthographic projection of the first output signal line G-out1 on the base substrate passes over the sub region between the first component part Part1 and the display area, that is, crosses over the sub region between the first component part Part1 and the display area, that is, the first output signal line G-out1 crosses over the shift register unit GOA (n) between the first component part Part1 and the display area, and the first output line further needs to be separated from the orthographic projections of the pull-up node PU and the pull-down node PD in the crossed shift register unit GOA (n) on the base substrate, that is, the first output signal line G-out1 avoids the pull-up node PU and the pull-down node PD in the shift register unit GOA (n) corresponding to the crossed sub region, in order to reduce the noise impact on the pull-up node PU and the pull-down node PD in the crossed shift register unit GOA (n). Similarly, the orthographic projection of the second output signal line G-out2 on the base substrate passes over the sub region between the second component part Part2 and the display area, that is, the second output signal line G-out2 crosses over the sub region between the second component part Part2 and the display area, and further the second output signal line G-out2 crosses over the shift register unit GOA (n) between the second component part Part2 and the display area, and the second output signal line G-out2 further needs to be separated from the orthographic projections of the pull-up node PU and the pull-down node PD in the crossed shift register unit GOA (n) on the base substrate, that is, the second output signal line G-out2 avoids the pull-up node PU and the pull-down node PD in the crossed shift register unit GOA (n) to reduce the noise impact on the pull-up node PU and the pull-down node PD in the crossed shift register unit GOA (n).

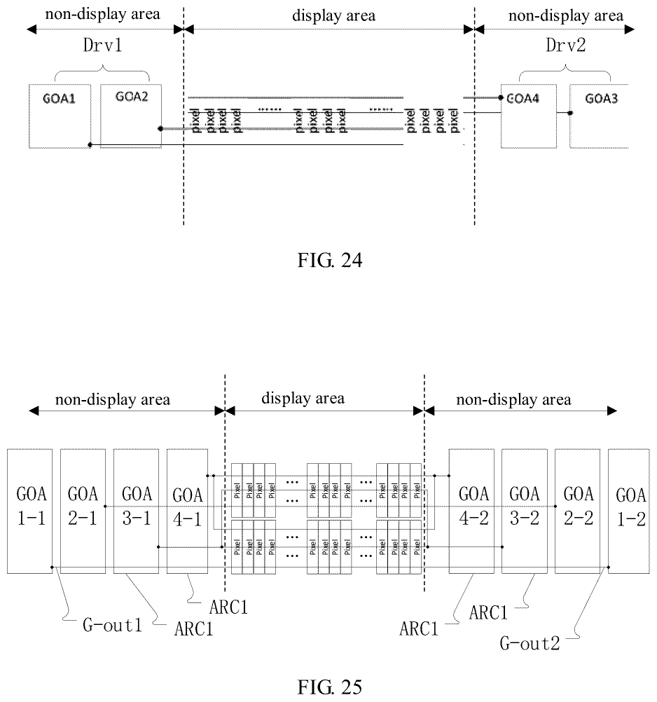

FIG. 24 is a schematic view of the layout structure of the gate driving circuit according to another embodiment of the present disclosure. In the figure, GOA1 represents the first gate driving circuit, GOA2 represents the second gate driving circuit, and so on. As shown in FIG. 24, in the exemplary embodiment, the multiple gate driving circuits GOA include a first driving group Drv1 and a second driving group Drv2 arranged on both sides of the display area; wherein, in each output signal line G-out of the same driving group, the orthographic projection of the output signal line G-out connected to the shift register unit GOA (n) far away from the display area on the base substrate is separated from the orthographic projections of the pull-up node PU and the pull-down node PD in the shift register unit GOA (n) close to the display area on the base substrate. Wherein, the display panel usually includes multiple gate driving circuits GOA, and different gate driving circuits GOA output gate driving signals with different functions. Multiple gate driving circuits GOA include the first driving group Drv1 and the second driving group Drv2 arranged on both sides of the display area. That is, a part of the gate driving circuit GOA of the display panel is on one side of the display area, and another part of the gate driving circuit GOA is on the other side of the display area. Each gate driving circuit GOA is a single-sided drive, that is, each stage of the shift register units GOA (n) in each gate driving circuit GOA provide gate driving signals from the same side of the display area to the display area. As shown in FIG. 24, the display panel may include the first to fourth gate driving circuits GOA1 to GOA4. The first gate driving circuit GOA1 and the second gate driving circuit GOA2 are on the same side of the display area, forming the first driving group Dv1. The third gate driving circuit GOA3 and the fourth gate driving circuit GOA4 are on the other side of the display area, forming the second driving group Dv2.

In each output signal line G-out of the same driving group, the output signal line G-out connected to the shift register unit GOA (n) far away from the display area crosses over the shift register unit GOA (n) close to the display area, and the orthographic projection of the output signal line G-out connected to the shift register unit GOA (n) far away from the display area on the base substrate is separated from the orthographic projections of the pull-up node PU and pull-down node PD of the shift register unit GOA (n) close to the display area on the base substrate, that is, the orthographic projection of the output signal line G-out connected to the shift register unit GOA (n) far away from the display area is separated from the orthographic projections of the pull-up node PU and the pull-down node PD in the crossed shift register unit GOA (n) on the base substrate, in order to avoid the pull-up node PU and the pull-down node PU in the crossed shift register unit GOA (n) and reduce noise interference to the pull-up node PU and the pull-down node PD in the crossed shift register unit GOA (n).

FIG. 25 is a schematic view of the layout structure of the gate driving circuit according to another embodiment of the present disclosure. In the figure, GOA1 represents the first gate driving circuit, GOA2 represents the second gate driving circuit, and so on. As shown in FIG. 25, in the exemplary embodiment, multiple gate driving circuits GOA include at least one first structured gate driving circuit ARC1, and each stage of the shift register unit GOA (n) in the first structured gate driving circuit ARC1 is connected to multiple output signal lines G-out; wherein, the orthographic projection of any output signal line G-out connected to the first structured gate driving circuit ARC1 on the base substrate is separated from the orthographic projections of the pull-up node PU and the pull-down node PD in the shift register unit GOA (n) between the first structured gate driving circuit ARC1 and the display area on the base substrate.

In this exemplary embodiment, each stage of the shift register unit GOA (n) in the first structured gate driving circuit ARC1 is connected to multiple output signal lines G-out, that is, one shift register unit GOA (n) of the first structured gate driving circuit ARC1 drives multiple pixel rows, that is, multiple pixel rows share one stage of the shift register unit GOA (n). The “multiple” mentioned herein refers to two or more.

For example, one stage of the shift register unit GOA (n) of the first structured gate driving circuit ARC1 outputs two rows of gate driving signals, that is, one stage of the shift register unit GOA (n) drives two rows of sub pixels.

In this structure, the orthographic projection of the output signal line G-out connected to the first structured gate driving circuit ARC1 on the base substrate crosses over the shift register unit GOA (n) between the first structured gate driving circuit ARC1 and the display area. And, the orthographic projection of the output signal line G-out connected to the first structured gate driving circuit ARC1 on the base substrate is separated from the orthographic projections of the pull-up node PU and the pull-down node PD of the shift register unit GOA (n) between the first structured gate driving circuit ARC1 and the display area on the base substrate, that is, the output signal line G-out connected to the first structured gate driving circuit ARC1 avoids the pull-up node PU and the pull-down node PD of any shift register unit GOA (n) between the first structured gate driving circuit ARC1 and the display area, in order to reduce noise interference on the pull-up node PU and the pull-down node PD of the shift register unit GOA (n) between the first structured gate driving circuit ARC1 and the display area.

In addition, it should be understood that in this exemplary embodiment, all gate driving circuits GOA may be the first structured gate driving circuit ARC1, that is, all gate driving circuits GOA are that onestage of the shift register units GOA (n) drives multiple pixel rows. Alternatively, a part of the gate driving circuit GOA may be the first structured gate driving circuit ARC1, as shown in FIG. 25, among the first to fourth gate driving circuits GOA1 to GOA4, the third and fourth gate driving circuits GOA3 and GOA4 are the first structured gate driving circuit ARC1, while the first and second gate driving circuits GOA1 and GOA2 are conventional structures. There is no special limitation on the number of first structured gate driving circuits ARC1 in the present disclosure.

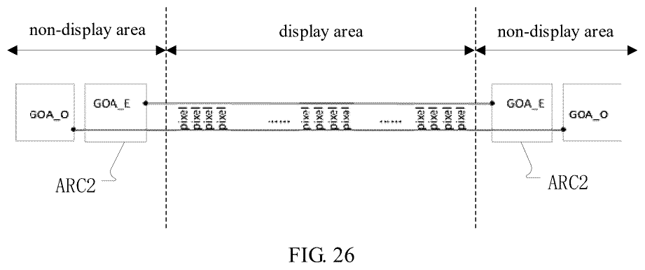

FIG. 26 is a schematic view of the layout structure of the gate driving circuit according to another embodiment of the present disclosure. In the figure, GOA1 represents the first gate driving circuit, GOA2 represents the second gate driving circuit, and so on. As shown in FIG. 26, in an exemplary embodiment, multiple gate driving circuits GOA include at least one second structured gate driving circuit ARC2. Each stage of the shift register unit GOA (n) of the second structured gate driving circuit ARC2 includes first and second sub shift register units GOA (n1) and GOA (n2) arranged oppositely on both sides of the display area. The first and second sub shift register units GOA (n1) and GOA (n2) respectively provide gate driving signals to the same row of sub pixels through corresponding output signal lines G-out; wherein, the orthographic projection of any output signal line G-out connected to the second structured gate driving circuit ARC2 on the base substrate is separated from the orthographic projections of the pull-up node PU and the pull-down node PD of the shift register unit GOA (n) between the second structured gate driving circuit ARC2 and the display area on the base substrate.

In this exemplary embodiment, each stage of the shift register unit GOA (n) of the second structured gate driving circuit ARC2 includes the first sub shift register unit GOA (n1) and the second sub shift register unit GOA (n2) arranged opposite each other on both sides of the display area, and the first sub shift register unit GOA (n1) and the second sub shift register unit GOA (n2) respectively provide gate driving signals to the same row of sub pixels through corresponding output signal lines G-out. That is, each stage of the shift register unit GOA (n) of the second structured gate driving circuit ARC2 includes two parts, and the two parts are on both sides of the display area. Furthermore, each stage of the shift register units GOA (n) of the second structured gate driving circuit ARC2 provide the same gate driving signal to the same row of sub pixels simultaneously on both sides of the display area. For example, the transistors of the pixel circuit of the display area are double gate structures, and the second structured gate driving circuit ARC2 is used to provide gate driving signals to the transistors of the double gate structure. The first sub shift register unit GOA (n1) provides gate driving signals to one gate of the transistor from one side of the display area, and the second sub shift register unit GOA (n2) provides gate driving signals to the other gate of the transistor from the other side of the display area.

In addition, the present disclosure further provides a display device, which may include the display panel described in any of the above embodiments.

Those skilled in the art will easily come up with other embodiments of the present disclosure after considering the specification and practicing the invention disclosed herein. The present application is intended to cover any variations, applications, or adaptive changes of the present disclosure, which follow the general principles of the present disclosure and include common knowledge or customary technical means in the art not disclosed in the present disclosure. The specification and embodiments are only considered exemplary, and the true scope and spirit of the present disclosure are indicated by the claims.

1. A display panel, comprising a display area and a non-display area being provided around the display area, wherein the non-display area comprises multiple gate driving circuits, the gate driving circuit comprises multiple shift register units cascaded, and the shift register units in each gate driving circuit that provides gate driving signals for sub pixels in a same row is in the same row; the display panel further comprising:
a base substrate comprising the display area and the non-display area, and the non-display area comprises multiple sub regions arranged in an array in row and column directions, each sub region in a same column corresponds to each stage of shift register units in a same gate driving circuit, and each sub region in a same row corresponds to a same stage of shift register units of each gate driving circuit;
a second source drain metal layer provided on one side of the base substrate, the second source drain metal layer comprising:
multiple output signal lines, orthographic projections of the multiple output signal lines on the base substrate extending along a row direction, and the output signal lines are arranged corresponding to the shift register units respectively;
wherein, among multiple output signal lines in a same pixel row, an orthographic projection of a output signal line connected to a shift register unit far away from the display area on the base substrate crosses a sub region corresponding to a shift register unit near the display area, and output signal lines of a same pixel row are separated from each other.

2. The display panel according to claim 1, wherein the shift register unit comprises a pull-up node and a pull-down node, the pull-up node is used to control a output transistor connected to it to output a conductive level, and the pull-down node is used to control a output transistor connected to it to output a non-conductive level;
wherein, an orthographic projection of a output signal line connected to a shift register unit far away from the display area on the base substrate is separated from orthographic projections of the pull-up node and the pull-down node of a shift register unit close to the display area on the base substrate.

3. The display panel according to claim 2, wherein the display panel further comprises:
a first conductive layer provided on a side of the base substrate facing the second source drain metal layer, the first conductive layer comprising:
a first connection line, an orthographic projection of the first connection line on the base substrate extending along the row direction, the first connection line being used to form the pull-up node;
a second connecting line, an orthographic projection of the second connecting line on the base substrate extending along the row direction, the second connecting line being used to form the pull-down node;
wherein, orthographic projections of the first and second connection lines of any Nth row of the gate driving circuit close to the display area on the base substrate are between orthographic projections of a Nth row output signal line and a N+1th row output signal line of the gate driving circuit far away from the display area on the base substrate, where N is a natural number.

4. The display panel according to claim 2, wherein the gate driving circuits are on a same side of the display area.

5. The display panel according to claim 2, wherein at least a portion of the gate driving circuit comprises a first component part and a second component part arranged oppositely on both sides of the display area, a shift register unit of the first component part is connected to some sub pixels of the display area through a first output signal line connected to it, and a shift register unit of the second component part is connected to other sub pixels of the display area through a second output signal line connected to it;
wherein, an orthographic projection of any of the first output signal lines on the base substrate is separated from orthographic projections of the pull-up and pull-down nodes of a shift register unit between a first component part and the display area on the base substrate, and an orthographic projection of any of the second output signal lines on the base substrate is separated from orthographic projections of the pull-up and pull-down nodes of a shift register unit between a second component part and the display area on the base substrate.

6. The display panel according to claim 2, wherein the multiple gate driving circuits comprise a first driving group and a second driving group arranged on both sides of the display area;
wherein, among output signal lines of the same driving group, an orthographic projection of a output signal line connected to a shift register unit far away from the display area on the base substrate is separated from orthographic projections of the pull-up node and the pull-down node of a shift register unit close to the display area on the base substrate.

7. The display panel according to claim 2, wherein the multiple gate driving circuits include at least one first structured gate driving circuit, and each stage of the shift register units of the first structured gate driving circuit is connected to multiple output signal lines;
wherein, an orthographic projection of any output signal line connected to the first structured gate driving circuit on the base substrate is separated from orthographic projections of the pull-up and pull-down nodes of a shift register unit between the first structured gate driving circuit and display area on the base substrate.

8. The display panel according to claim 2, wherein multiple gate driving circuits comprises at least one second structured gate driving circuit, each stage of the shift register units of the second structured gate driving circuit comprises a first sub shift register unit and a second sub shift register unit arranged oppositely on both sides of the display area, and the first and second sub shift register units respectively provide gate driving signals to sub pixels in a same row through corresponding output signal lines;
wherein, an orthographic projection of any output signal line connected to the second structured gate driving circuit on the base substrate is separated from orthographic projections of the pull-up and pull-down nodes of a shift register unit between the second structured gate driving circuit and display area on the base substrate.

9. The display panel according to claim 3, wherein the shift register unit further comprises a first transistor and a second transistor, a gate of the first transistor is connected to the pull-up node, a first pole of the first transistor receives a first signal, and a second pole of the first transistor is connected to a output terminal; a gate of the second transistor is connected to the pull-down node; the display panel further comprises:
an active layer provided on a side of the base substrate facing the second source drain metal layer, the active layer comprising:
multiple first active structures, orthographic projections of the multiple first active structures on the base substrate extending along the column direction and distributed at intervals in the row direction, the first active structure comprising at least a first active portion and second and third active portions connected to both sides of the first active portion in the column direction, the first active portion being used to form a channel region of the first transistor, and the second and third active portions being used to form first and second poles of the first transistor;
multiple second active structures, orthographic projections of the multiple second active structures on the base substrate extending along the column direction and distributed at intervals in the row direction, the second active structure comprising at least a fourth active portion and fifth and sixth active portions connected to both sides of the fourth active portion in the column direction, the fourth active portion being used to form a channel region of the second transistor, and the fifth and sixth active portions being used to form first and second poles of the second transistor;
the first conductive layer further comprises:
a first gate line, an orthographic projection of the first gate line on the base substrate extending along the row direction and covering an orthographic projection of the first active portion on the base substrate, a part structure of the first gate line being used to form a gate of the first transistor, and the first gate line being connected to the first connection line;
a second gate line, an orthographic projection of the second gate line on the base substrate extending along the row direction and covering an orthographic projection of the fourth active portion on the base substrate, a part structure of the second gate line being used to form a gate of the second transistor, and the second gate line being connected to the second connection line.

10. The display panel according to claim 9, wherein one of the first active structures comprises a first structural portion, a second structural portion, and a third structural portion sequentially connected in the column direction, both the first structural portion and the third structural portion comprise two of the first active portions and one of the third active portions, and the second structural portion comprises one of the second active portions; the first conductive layer comprises four of the first gate lines, and the first connection lines are respectively connected to each of the first gate lines;
the display panel further comprises:
a first source drain metal layer provided on a side of the first conductive layer facing the second source drain metal layer, the first source drain metal layer comprises:
a first transmission line, an orthographic projection of the first transmission line on the base substrate extending along the row direction and on an orthographic projection of the second active portion on the base substrate, the first transmission line is connected to each of the second active portions through a via to output a first signal to the first transistor;
a second transmission line for forming the output terminal, an orthographic projection of the second transmission line on the base substrate extending along the row direction and on an orthographic projection of the third active portion on the base substrate, the second transmission line is connected to corresponding third active portion and output signal line through a via respectively to connect a second pole of the first transistor to the output terminal.

11. The display panel according to claim 10, wherein a first pole of the second transistor receives a second signal, and a second pole is connected to the output terminal; one of the second active structures comprises a fourth structural portion, a fifth structural portion, and a sixth structural portion sequentially connected in the column direction, the fourth structural portion and the sixth structural portion each comprise two of the fourth active portions and one of the sixth active portions, and the fifth structural portion comprises one of the fifth active portions; the first conductive layer comprises four of the second gate lines, and the second connection lines are respectively connected to each of the second gate lines;
the first source drain metal layer further comprises:
a third transmission line, an orthographic projection of the third transmission line on the base substrate extending along the row direction and on an orthographic projection of the fifth active portion on the base substrate, the third transmission line is connected to each of the fifth active portions through a via to output a second signal to the second transistor;
a fourth transmission line, an orthographic projection of the fourth transmission line on the base substrate extending along the row direction and on an orthographic projection of the sixth active portion on the base substrate, the fourth transmission line is connected to corresponding sixth active portion and output signal line through a via respectively to connect a second pole of the second transistor to the output terminal.

12. The display panel according to claim 3, wherein the shift register unit further comprises a first capacitor and a second capacitor, a first pole of the first capacitor is connected to the pull-up node, and a second pole of the first capacitor is connected to the output terminal; a first pole of the second capacitor is connected to the pull-down node, and a second pole of the second capacitor is connected to the output terminal;
wherein, a capacitance value of the first capacitor and a capacitance value of the second capacitor are both greater than or equal to 2 pF.

13. The display panel according to claim 12, wherein the second connection line is on a side of the first connection line near the display area;
the first conductive layer further comprises:
a first conductive portion, which is connected to a side of the first connection line in the row direction near the display area, and is used to form the first pole of the first capacitor;
a second conductive portion, which is connected to a side of the second connection line in the row direction near the display area, and is used to form the first pole of the second capacitor;
the display panel further comprises:
a second conductive layer between the first conductive layer and the second source drain metal layer, wherein the second conductive layer comprises:
a third conductive portion, an orthographic projection of the third conductive portion on the base substrate overlaps at least partially with an orthographic projection of the first conductive portion on the base substrate, and the third conductive portion is used to form the second pole of the first capacitor;
a fourth conductive portion, an orthographic projection of the fourth conductive portion on the base substrate overlaps at least partially with an orthographic projection of the second conductive portion on the base substrate, and the fourth conductive portion is used to form the second pole of the second capacitor;
a first source drain metal layer provided on a side of the second conductive layer facing the second source drain metal layer, and the first source drain metal layer comprises:
a fifth conductive portion, an orthographic projection of the fifth conductive portion on the base substrate overlaps at least partially with an orthographic projection of the second conductive portion on the base substrate, and the fifth conductive portion is connected to the first conductive portion through a via;
a sixth conductive portion, an orthographic projection of the sixth conductive portion on the base substrate overlaps at least partially with an orthographic projection of the fourth conductive portion on the base substrate, and the sixth conductive portion is connected to the second conductive portion through a via.

14. The display panel according to claim 3, wherein the display panel further comprises a second conductive layer, a first source drain metal layer, and a first planarization layer sequentially stacked on a side of the first conductive layer facing the second source drain metal layer;
wherein, a thickness of the first planarization layer is greater than or equal to 2000 nm.

15. The display panel according to claim 14, wherein the display panel further comprises:
an interlayer insulating layer provided between the second conductive layer and the first source drain metal layer;
wherein, a ratio of the thickness of the first planarization layer to a thickness of the interlayer insulation layer is greater than or equal to 4.

16. The display panel according to claim 14, wherein the display panel further comprises:
a first passivation layer, the first passivation layer covers the first planarization layer on a side of the first planarization layer away from the base substrate, and a thickness of the first passivation layer is smaller than the thickness of the first planarization layer.

17. The display panel according to claim 14, wherein the shift register unit further comprises a first capacitor and a second capacitor, a first pole of the first capacitor is connected to the pull-up node, and a second pole of the first capacitor is connected to the output terminal; a first pole of the second capacitor is connected to the pull-down node, and a second pole of the second capacitor is connected to the output terminal; the second connection line is located on a side of the first connection line near the display area;
the first conductive layer further comprises:
a first conductive portion, which is connected to a side of the first connection line in the row direction near the display area, and is used to form the first pole of the first capacitor;
a second conductive portion, which is connected to a side of the second connection line in the row direction near the display area, and is used to form the first pole of the second capacitor;
the second conductive layer comprises:
a third conductive portion, an orthographic projection of the third conductive portion on the base substrate overlaps at least partially with an orthographic projection of the first conductive portion on the base substrate, and the third conductive portion is used to form the second pole of the first capacitor;
a fourth conductive portion, an orthographic projection of the fourth conductive portion on the base substrate overlaps at least partially with an orthographic projection of the second conductive portion on the base substrate, and the fourth conductive portion is used to form the second pole of the second capacitor;
the first source drain metal layer comprises:
a fifth conductive portion, an orthographic projection of the fifth conductive portion on the base substrate overlaps at least partially with an orthographic projection of the second conductive portion on the base substrate, and the fifth conductive portion is connected to the first conductive portion through a via;
a sixth conductive portion, an orthographic projection of the sixth conductive portion on the base substrate overlaps at least partially with an orthographic projection of the fourth conductive portion on the base substrate, and the sixth conductive portion is connected to the second conductive portion through a via;
the second source drain metal layer further comprises:
a seventh conductive portion, an orthographic projection of the seventh conductive portion on the base substrate overlaps at least partially with an orthographic projection of the fifth conductive portion on the base substrate, and the seventh conductive portion is connected to the third conductive portion through a via;
an eighth conductive portion, an orthographic projection of the eighth conductive portion on the base substrate overlaps at least partially with an orthographic projection of the sixth conductive portion on the base substrate, and the eighth conductive portion is connected to the fourth conductive portion through a via;
wherein, the first planarization layer has a first hollow portion facing the seventh conductive portion and a second hollow portion facing the eighth conductive portion, the first hollow portion exposes the seventh conductive portion and the second hollow portion exposes the eighth conductive portion.

18. A display device comprising the display panel according to claim 1.

19. A display device comprising the display panel according to claim 2.

20. A display device comprising the display panel according to claim 3.
